(19) United States
(12) Patent Application Publication
(10) Pub. No.: US 2010/0218372 A1
(43) Pub. Date: Sep. 2, 2010

(54) METHOD OF SOLDERING COMPONENTS ON CIRCUIT BOARDS AND CORRESPONDING CIRCUIT BOARD

(75) Inventor: Tiziano Amarilli, Preganziol-Treviso (IT)

Correspondence Address: Viering, Jentschura & Partner - OSR, 3770 Highland Ave., Suite 203, Manhattan Beach, CA, 90266, US

(73) Assignee: OSRAM GESELLSCHAFT MIT BESCHRAENKTER HAFTUNG, Muenchen (DE)

(21) Appl. No.: 12/738,078

(22) PCT Filed: Oct. 25, 2007
(86) PCT No.: PCT/IT07/00744

§ 371 Date: Apr. 15, 2010

(51) Int. Cl. H05K 3/30; H05K 3/34

(52) U.S. Cl. 29/837; 29/840

(57) ABSTRACT

A method of mounting on a circuit board a component having at least one pin extending therefrom for insertion into a respective hole provided in said circuit board, wherein said component has a coating extending over the proximal end of said at least one pin, said extension of the coating having a circular cross-section is provided. The method may include forming said respective hole as a non noncircular hole.

### FIELD OF THE INVENTION

The invention relates to arrangements for soldering components on circuit boards.

The invention was devised by paying specific attention to its possible use in soldering on circuit boards such as Printed Circuit Boards (PCBs) components provided with pins having a proximal part (i.e. the part of the pin closer to the body of the component) covered by a coating.

Ceramic components covered by a lacquer over the body of the component and the proximal parts of the pins are exemplary of such components.

### DESCRIPTION OF THE RELATED ART

When components of the type considered in the foregoing are to be soldered onto a circuit board, the holes drilled into the board for insertion of the pins may be occluded by the coating covering the distal parts of the pins. This undesired event may occur if the component is positioned close enough to the board to cause the coating to contact and occlude (“plug”) the hole thus leaving no free space available for the air to exit the hole during the soldering process.

Air remaining trapped in the soldering mass (e.g. tin) once this is solidified lies at the basis of the undesired phenomenon known as “blown soldering”. This is an incomplete soldering due to the air trapped and thus remaining interposed between the soldering mass and the metal connections on the circuit board.

Blown soldering is known to represent a hazard in terms of quality because it prevents good electrical connection of a component to the corresponding circuit. A defective, blown soldering is generally rather difficult to detect.

Properly avoiding blown soldering is particularly important in the case of components that are machine-mounted (i.e. mounted automatically) onto the circuit board. In that case, larger holes are typically drilled into the board in order to facilitate insertion of the component pins therein. A defective, blown soldering causes additional problems due to the higher current density across the soldering tin.

Attempts at solving the problems outlined in the foregoing have heretofore involved using pre-formed components, namely components provided with pins that are properly shaped (e.g. according to a general S-shape or Z-shape) in such a way to prevent the proximal ends of the pins—and thus the coating (e.g. lacquer) coated thereon—to come into contact with the holes drilled in the circuit board thus avoiding any risk that this holes may be undesirably occluded by the coating/lacquer.

This approach represents a viable solution as long as no specific restrictions have to be dealt with in respect of e.g. the height of the components, the spacing to the other components onto the circuit board, Radio Frequency Interference (RFI) issues and so on.

### OBJECT AND SUMMARY OF THE PRESENT INVENTION

The preceding discussion indicates that the need is still felt for arrangements which, on the one hand, may prevent the occurrence of undesired phenomena such as blown soldering and, on the other hand, do not impose any specific restrictions on the characteristics of the components to be mounted on the circuit board and/or the requirements to be complied with in mounting the components on the board.

The object of the invention is to provide such a solution.

According to the invention, that object is achieved by means of a method having the features set forth in the claims that follow. The invention also relates to a corresponded circuit board (such as e.g. a Printed Circuit Board or PCB).

The claims are an integral part of the disclosure of the invention as provided herein.

An embodiment of the invention is thus a method of mounting on a circuit board a component having at least one pin extending therefrom for insertion into a respective hole provided in the circuit board, wherein said component has a coating extending over the proximal end of said at least one pin, said extension of the coating having an circular cross-section, and wherein the method includes the step of forming said respective hole as a noncircular hole.

Embodiments of the invention lead to a significant advantage in terms of time spared in quality checking irrespective of whether this is performed manually or by optical apparatus. Also, the inherent difficulties encountered in locating and detecting blown soldering (which quite frequently has the same appearance of normal soldering) may be avoided.

Embodiments of the invention do not compromise the mechanical assembly in that the shape of the holes in the circuit board also facilitates component insertion in the circuit board (especially if performed mechanically).

The experimental results obtained so far by the applicant in respect of even large quantities of circuits have shown a 100% reproducibility with no failures. Such a result cannot be generally guaranteed in the case of a conventional circular drill with subsequent automatic or manual visual control of production.

The soldering process as described herein results in a better final quality of the whole electrical product: good soldering in fact results in improved product reliability over time and increased safety in use thereof.

Additionally, resorting to “preformed” components can be avoided, which is advantageous in terms of cost due to the possibility of using standard, non preformed components.

The arrangement described herein can be extended to other components that have the same characteristics described in the foregoing and are thus exposed to blown soldering.

### BRIEF DESCRIPTION OF THE DRAWINGS

The invention will now be described, by way of example only, with reference to the annexed figures of drawing, wherein:

FIG. 1 is a perspective view generally illustrative of a component mounted onto a circuit board,

FIGS. 2 and 3 are two schematic views representative of the principle underlying the arrangement described herein,

FIG. 4 is further illustrative of operation of the arrangement described herein, and

FIG. 5 a schematically representative of certain features of the arrangement described herein.

### DETAILED DESCRIPTION OF EMBODIMENTS

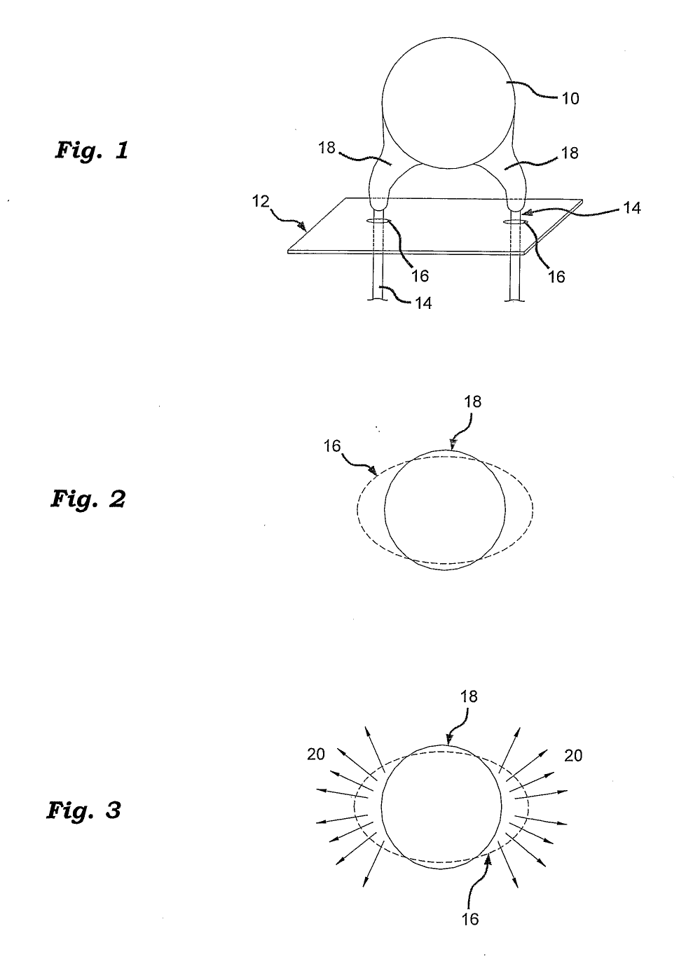

As indicated, FIG. 1 is generally representative of mounting an electrical component such as e.g. a resistor, capacitor or the like onto a circuit board 12 typically in the form of a Printed Circuit Board or PCB.

The component 10 is provided with one or more contact pins 14 (two pins are shown in the exemplary embodiment of FIG. 1) to be inserted into respective holes 16 provided (“drilled”) in the circuit board 12.

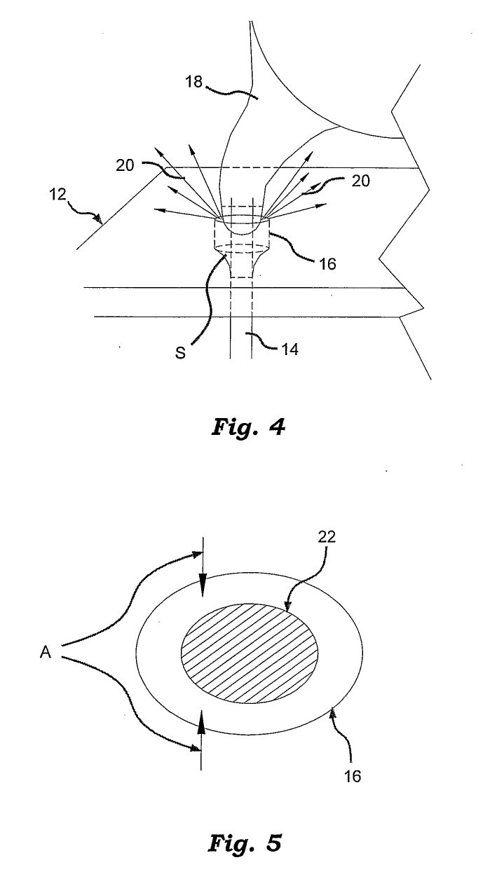

Once the pins 14 are inserted into the respective holes 16, a soldering mass S such as tin (schematically shown only on FIG. 4) is applied—e.g. by means of a “wave soldering” technique—to provide mechanical connection of the component 10 to the board 12 as well as electrical connection of the pins 14 to conductive strips/layers (not shown in detail in the figures) provided on the board 12, e.g. at the underside thereof.

The exemplary component 10 is a component having a coating thereon as is the case of so-called “ceramic” components. As a result of the coating process, the coating applied onto the component 10 will generally extend also over the proximal portions of the pins 14, namely the ends of the pins 14 which are closer to the body of the component 10.

In the exemplary representation of FIG. 1, reference numerals 18 indicate two extensions of the coating (e.g. lacquer) applied over the component 10 and extending over the proximal parts of the pins 14.

Due to the process currently used to apply such a coating/lacquer (namely a fluid/flowable coating mass which is subsequently consolidated) each extension 18 will general have a cross section (i.e. a section taken in a plane generally orthogonal to the direction of extension of the pin 14) which is substantially circular. This circular shape is shown in both FIGS. 2 and 3, which can be seen as representative of the outer contour of the cross section of the extension 18 at a location near the outmost free end of the extension 18.

Those of skill in the art will otherwise appreciate that, in order to better highlight the structural details, the various elements/parts shown in the figures are not drawn to precise scale. This also applies to the pins 14 which are generally shown in FIGS. 1 and 4 as of indefinite length.

In an embodiment of the arrangement described herein, the contour or profile of the hole 16 is “noncircular”.

As described herein the hole 16 will be assumed to have such a contour or profile over its whole extension through the circuit board 12, i.e. such a cross sectional shape in a family of planes orthogonal to the axis of the hole 16 (which essentially corresponds to the axis of the portion of the pin 14 extending through the hole 16).

The exemplary hole 16 considered herein will thus generally have a constant, uniform cross section down the whole extension of the hole 16 through the circuit board 12. However, those of skill in the art will promptly appreciate that this requirement is not mandatory, in that the “noncircular” feature may be present only at the mouth portion of the hole 16 as schematically shown in dashed lines in FIGS. 2 and 3.

Such a noncircular hole shape will in any case exclude a precise matching condition between the hole 16 and the essentially round cross section of the coating 18. The absence of such matching condition will ensure that in any case, even if coming into contact with the circuit board 12, and thus with the mouth portion of the hole 16, the coating 18 will intrinsically be unable to occlude the hole 16.

As a result, escape pathways generally designated 20, will always exist permitting air to escape from the hole 16 during the soldering process, thus preventing the undesired occurrence of “blown soldering”.

As used herein, “noncircular” is intended to encompass any shape which is different from a circular shape.

A circular is the shape of a curve comprised of points all having the same distance to a common centre.

A noncircular shape will thus encompass i.a. a polygonal shape, a lobe-like shape (such as a flower-like shape), a cardioid-like shape, an oval shape or an elliptical shape as shown herein. All these shapes have in common the feature of being defined by a curve comprised of points that fail to exhibit an equal distance to a common centre.

Irrespective of the relative dimensions, such a noncircular shape will be unable to provide a precise match to a circular shape and will thus inevitably leave a gap therebetween adapted to define the escape pathways 20 shown in the drawings.

The noncircular holes 16 in the board 12 as described herein solve the problem of blown soldering also avoiding any undesired incomplete soldering. In fact the extensions 18 of the coating extending over the pins 14 will in any case be unable to obstruct a hole 16 that is noncircular; escape pathways 20 will thus always exist permitting air to escape from the holes 16 during the soldering process.

It will be appreciated that the advantages of such an arrangement are retained irrespective of the relative dimensions of the parts involved.

In the exemplary embodiment shown herein, the holes 16 have an oval/elliptical shape. This was found to be particularly advantageous in terms of the processes adopted for providing such holes in the circuit board 12.

FIG. 5 is a schematic representation of a cutting pin 22 adopted for forming an oval/elliptical hole 16 in the circuit board 12. The arrows A are representative of the cutting direction adopted for forming a noncircular hole 16 by using a cutting pin 22 which has a cross-section shape which is similarly non circular. In an embodiment, the cutting/drilling pin 22 has a shape which reproduces (by way of homothety) the shape of the hole 16.

A noncircular shape for the hole or holes 16 was also found to be advantageous in that it improves the process of inserting the pins 14 into the holes 10 during automatic mounting of components 10 onto a board 12.

Specifically, the tool in the automatic mounting machinery which separates the component 10 from the tape out of which the component is usually derived and/or which treads the components out of the bulk out of which the component 18 is extracted for insertion, can be operated along the main dimension (i.e. the longer axis) of the hole 16—i.e. orthogonal to the main direction of operation of the cutting pin 22. This arrangement was found to advantageously relax the requirements in terms of positioning of the mounting tool.

Without prejudice to the underlying principle of the invention, the details and embodiments may vary, even significantly, with respect to what has been described and illustrated by way of example only, without departing from the scope of the invention as defined in the annexed claims.

1. A method of mounting on a circuit board a component having at least one pin extending therefrom for insertion into a respective hole provided in said circuit board, wherein said component has a coating extending over the proximal end of said at least one pin, said extension of the coating having a circular cross-section,
the method comprising: forming said respective hole as a non noncircular hole.

2. The method of claim 1,
wherein said noncircular hole is an oval hole.

3. The method of claim 1, further comprising:
providing a cutting tool to cut said respective hole in said circuit board,
wherein said cutting tool is noncircular.

4. The method of claim 3,
wherein said noncircular cutting tool reproduces by homothety said noncircular hole.

5. The method of claim 3,
wherein said noncircular hole is cut in said circuit board by moving said cutting tool in a direction across a main dimension of said noncircular hole.

6. The method of claim 1, further comprising:
inserting said at least one pin into said respective hole by means of a relative movement along a main dimension of said noncircular hole.

7. The method of claim 1, further comprising:
applying a soldering mass to said at least one pin inserted into said noncircular hole, wherein said noncircular hole defines escape pathways for air within said at least one hole, thereby preventing air from being trapped therein while said soldering mass is applied.

8. The method of claim 1,
wherein said coating is a lacquer applied onto said component.

9. A circuit board for mounting components thereon, said board comprising at least one hole for insertion of a respective pin in a component to be mounted on said board,
wherein said at least one hole is a noncircular hole.

10. The circuit board of claim 9,
wherein said noncircular hole is an oval hole.

11. The method of claim 1,
wherein said noncircular hole is an elliptical hole.

12. The circuit board of claim 9,
wherein said noncircular hole is an elliptical hole.
